(19) United States
(12) Patent Application Publication
(10) Pub. No.: US 2018/0175121 A1
(43) Pub. Date: Jun. 21, 2018

(54) PIXEL ARRANGEMENT STRUCTURE, ORGANIC LIGHT-EMITTING DIODE DEVICE, DISPLAY DEVICE AND MASK

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Fengli JI, Beijing (CN); Yinan LIANG, Beijing (CN); Shanshan BAI, Beijing (CN); Minghua XUAN, Beijing (CN); Liang SUN, Beijing (CN)

(21) Appl. No.: 15/127,215

(22) PCT Filed: Oct. 21, 2015
(86) PCT No.: PCT/CN2015/092403

§ 371 Date: Sep. 19, 2016

(30) Foreign Application Priority Data
May 18, 2015 (CN) 201510254661.1

(51) Int. Cl. H01L 27/32; H01L 51/52

(52) U.S. Cl. CPC H01L 27/3218; H01L 51/52; H01L 27/3246

(57) ABSTRACT

A pixel arrangement structure, an organic electroluminescent device (i.e., organic light-emitting diode device), a display device and a mask are provided, which can increase opening areas of a metal mask for forming the pixel arrangement structure, and improve the aperture ratio, the brightness, the service life and the image resolution of active matrix organic light-emitting diode (AMOLED) products. The pixel arrangement structure includes a plurality of pixels. Each pixel includes three sub-pixels of different colors; connecting lines of center points of the sub-pixels form equilateral triangles; and each sub-pixel has a shape of polygon with more than four sides.

### TECHNICAL FIELD

Embodiments of the present invention relate to a pixel arrangement structure, an organic light-emitting diode (OLED) device, a display device and a mask.

### BACKGROUND

In display technology of mobile phones and tablet PCs, active matrix organic light-emitting diode (AMOLED) panel has gradually become the mainstream of the next generation of displays due to advantages of autoluminescence, bright colors, low power consumption, wide viewing angle, or the like.

The self-luminous principle of the AMOLED includes: an indium tin oxide (ITO) semiconductor electrode and a metal electrode formed on a backplane respectively act as an anode and a cathode of the device; organic semiconductor materials and luminescent materials are evaporated on a substrate; when driven by a certain voltage, electrons and holes are respectively injected into an electron transport layer (ETL) and a hole transport layer (HTL) from the cathode and the anode, and are transferred to an emission layer (EML) respectively from the ETL and the HTL, and meet in the EML to form excitons to excite luminescent molecules; and the luminescent molecules are subjected to radiative relaxation and emit visible light.

Currently, people's requirements on the resolution and the brightness of mobile phones or tablet PCs are higher and higher, but the production of high-quality and high-resolution OLED displays still faces challenges. Fine metal mask (FMM) is one of the most critical technologies which restrict the development of high-resolution AMOLEDs. With the improvement of the resolution, the production of a metal mask for vapor deposition also becomes more and more difficult. Meanwhile, due to the improved resolution, distance between luminous areas of sub-pixels becomes smaller and smaller, and the problem of color blending of evaporated screens also becomes more and more severe. Particularly in the traditional strip-arranged red (R), green (G) and blue (B) sub-pixels, the length of an opening area of an FMM corresponding to each sub-pixel is long, so linear control is difficult, and it tends to occur color blending. In the traditional slot RGB arrangement mode, although the length of opening areas is not long and linear control is easy, in the manufacturing process of the opening areas of the FMM, certain metallic raw materials must be reserved between the opening areas of each slot and function as a rib, so that the area of the opening areas of the FMM of the sub-pixels can be reduced, and the aperture ratio of the OLED display device can be affected. In the case of low aperture ratio, the brightness and the service life of the OLED cannot satisfy the requirements, so that the yield of AMOLED products would be low, and the mass production of high-resolution AMOLED panels can be limited. The inventor provides a pentile pixel arrangement mode, but the arrangement mode has problems of worse image crosstalk and jaggies of oblique lines, and the like.

As described, the pixel arrangement structure in the traditional OLED device cannot solve problem of reduced opening areas of the metal mask on the premise of allowing no image crosstalk. Thus, the luminous area is small, the aperture ratio is low, and the brightness and the service life of products cannot satisfy the requirements, which lead to a low yield of the AMOLED products, and they also limit the mass production of high-resolution AMOLED panels.

### SUMMARY

Embodiments of the present invention provide a pixel arrangement structure. The pixel arrangement structure includes a plurality of pixels, each pixel including three sub-pixels with different colors, connecting lines of center points of the sub-pixels forming equilateral triangles; and each sub-pixel having a shape of polygon with more than four sides.

For example, in the pixel arrangement structure, the shape of each sub-pixel is a regular hexagon.

For example, the pixel arrangement structure further includes a plurality of repeatedly arranged pixel unit rows; each pixel unit row including at least one pixel unit group; each pixel unit group on each pixel unit row being formed by two pixels; a center point of a sub-pixel of the first color in the first pixel and center points of a sub-pixel of the second color and a sub-pixel of the third color in the second pixel being provided on the same straight line; center points of a sub-pixel of the second color and a sub-pixel of the third color in the first pixel and a center point of a sub-pixel of the first color in the second pixel being provided on the same straight line; and adjacent sides of any two adjacent sub-pixels being parallel to each other and have equal length.

For example, in the pixel arrangement structure, each pixel unit group on each pixel unit row includes two pixels which are respectively a first pixel and a second pixel; the first pixel and the second pixel being adjacent to each other, connecting lines of center points of three sub-pixels in the first pixel forming a regular triangle; and connecting lines of center points of three sub-pixels in the second pixel forming an inverted triangle.

For example, in the pixel arrangement structure, each pixel respectively includes a red (R) sub-pixel, a green (G) sub-pixel and a blue (B) sub-pixel; in each pixel unit group, a center point of a G sub-pixel in the first pixel and center points of an R sub-pixel and a B sub-pixel in the second pixel being sequentially arranged on a first straight line; center points of an R sub-pixel and a B sub-pixel in the first pixel and a center point of a G sub-pixel in the second pixel being sequentially arranged on a second straight line; the first straight line being parallel to the second straight line; and the two straight lines extending along the row provided with the pixel unit group.

For example, in the pixel arrangement structure, in a column direction, a pixel arranged in an odd column being the first pixel, and a pixel arranged in an even column being the second pixel; or a pixel arranged in the odd column is the second pixel, and a pixel arranged in the even column being the first pixel.

For example, in the pixel arrangement structure, the sub-pixel of the first color in the first pixel is adjacent to the sub-pixel of the second color or the sub-pixel of the third color in the second pixel in two adjacent columns of pixels; the sub-pixel of the second color in the first pixel is adjacent to the sub-pixel of the first color in the second pixel in the two adjacent columns of pixels; and the sub-pixel of the third color in the first pixel is adjacent to the sub-pixel of the first color in the second pixel in the two adjacent columns of pixels.

For example, in the pixel arrangement structure, opposite sides of any two adjacent sub-pixels are parallel to each other.

For example, in the pixel arrangement structure, the side length of each sub-pixel is equal to each other.

For example, in the pixel arrangement structure, distance between center points of any two adjacent sub-pixels with different colors is equal to each other.

Embodiments of present invention also provide an organic light-emitting diode (OLED) device, including a base substrate and the pixel arrangement structure on the base substrate.

Embodiments of present invention also provide a display device, including the OLED device.

Embodiments of present invention also provide a mask for forming the pixel arrangement structure, including: a substrate, and opening areas provided on the substrate and corresponding with the sub-pixels in the pixel arrangement structure one to one, respectively.

### BRIEF DESCRIPTION OF THE DRAWINGS

Simple description will be given below to the accompanying drawings of embodiments to provide a more clear understanding of the technical solutions of the embodiments of the present invention. It is apparent that the drawings described below only involve some embodiments of the present invention but are not intended to limit the present invention:

FIG. 1 is a schematic diagram of a pixel arrangement structure provided by an embodiment of the present invention;

FIG. 2 is a schematic diagram illustrating an arrangement of sub-pixels in different sub-pixel unit groups of any pixel unit group in an pixel arrangement structure provided by an embodiment of the present invention;

FIG. 3 is a schematic diagram illustrating a repeated arrangement of pixel unit groups in a pixel arrangement structure provided by an embodiment of the present invention;

FIG. 4 is a schematic diagram illustrating an arrangement of different sub-pixel unit groups in any pixel unit group of a pixel arrangement structure provided by an embodiment of the present invention;

FIG. 5 is a schematic structural view of a mask provided by an embodiment of the present invention; and

FIG. 6 is a schematic diagram illustrating a corresponding relationship between opening areas in the mask provided by an embodiment of the present invention and sub-pixels in a pixel arrangement structure provided by an embodiment of the present invention.

### DETAILED DESCRIPTION

In order to make objects, technical details and advantages of the embodiments of the invention apparent, technical solutions according to the embodiments of the present disclosure will be described clearly and completely as below in conjunction with the accompanying drawings of embodiments of the present disclosure. It is apparent that the described embodiments are only a part of but not all of exemplary embodiments of the present disclosure. Based on the described embodiments of the present disclosure, various other embodiments can be obtained by those of ordinary skill in the art without creative labor and those embodiments shall fall into the protection scope of the present disclosure.

Embodiments of the present invention provide a pixel arrangement structure, an OLED device, a display device and a mask, so that opening areas of a metal mask for forming the pixel arrangement structure can be large, and the aperture ratio can be improved, and the brightness, the service life and the image resolution of AMOLED products can be improved.

The pixel arrangement structure provided by embodiments of the present invention includes a plurality of pixels. Each pixel is formed by sub-pixels of different colors. Connecting lines of center points of the sub-pixels form equilateral triangles, so that the sub-pixels are arranged staggeredly in dot form. The shape of each sub-pixel has a shape of polygon with more than four sides, such as a pentagon, or a hexagon. As a luminous area of the pentagon or the hexagon is greater than that of a tetragonum, the luminous area is effectively increased and a non-luminous area is reduced. In addition, the opening areas of the metal mask for forming the pixel arrangement structure are also increased; the distance between the opening areas of the metal mask may be also increased; the strength of the metal mask is increased; the service life of the metal mask is prolonged; and the production cost is reduced. Moreover, the brightness and the service life of products can satisfy higher requirements; the yield of AMOLED products can be improved; the mass production of high-resolution AMOLED panels can be achieved; and the problem of image crosstalk is avoided, so that the display image resolution of screens is high.

For instance, the shape of each sub-pixel is a regular hexagon.

For instance, the pixel arrangement structure includes a plurality of repeatedly arranged pixel unit rows; each pixel unit row includes at least one pixel unit group; and each pixel unit group on each pixel unit row is formed by pixels.

For instance, each pixel unit group on each pixel unit row includes two pixels which are respectively a first pixel and a second pixel; the first pixel and the second pixel are adjacent to each other; connecting lines of center points of three sub-pixels in the first pixel form a regular triangle; and connecting lines of center points of three sub-pixels in the second pixel form an inverted triangle.

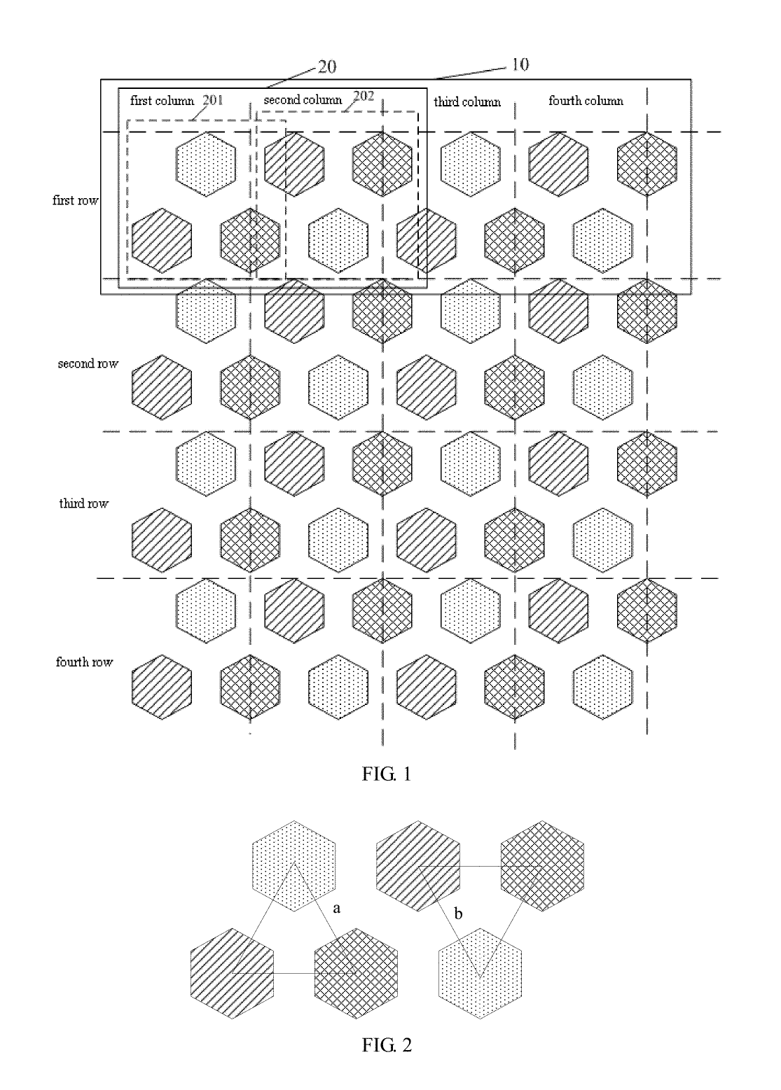

As illustrated in FIG. 1, the pixel arrangement structure provided by an embodiment of the present invention includes: a plurality of repeatedly arranged pixel unit rows 10. Each pixel unit row 10 includes at least one pixel unit group 20; each pixel unit group 20 on each pixel unit row includes a first pixel 201 and a second pixel 202 which are adjacent to each other; and the first pixel 201 and the second pixel 202 respectively include three sub-pixels with different colors. For instance, four pixel unit rows 10 are provided in FIG. 1, and each pixel unit row includes two pixel unit groups 20. When illustrated in the form of column, four pixel unit columns are provided, the first pixel 201 and the second pixel 202 disposed in the same row form a pixel unit group 20; and a third pixel and a fourth pixel in the same row form a pixel unit group 20, and so on.

As illustrated in FIG. 2, in each pixel unit group, the three sub-pixels in the first pixel are arranged in the shape of a regular triangle, and the three sub-pixels in the second pixel are arranged in the form of an inverted triangle. That is to say, connecting lines of a center point of a sub-pixel of the first color, a center point of a sub-pixel of the second color, and a center point of a sub-pixel of the third color in the first pixel form an equilateral triangle, and connecting lines of a center point of a sub-pixel of the first color, a center point of a sub-pixel of the second color, and a center point of a sub-pixel of the third color in the second pixel also form an equilateral triangle. Moreover, a connecting line a of the center point of the sub-pixel of the first color and the center point of the sub-pixel of the second color in the first pixel is parallel to a connecting line b of the center point of the sub-pixel of the first color and the center point of the sub-pixel of the third color in the second pixel.

In the embodiments of the present invention, the shape of each sub-pixel is a polygon of which the number of sides is greater than 4. For instance, in an embodiment of the present invention, the shape of each sub-pixel is a regular hexagon, and, it may also be a pentagon.

The pixel arrangement structure provided by embodiments of the present invention includes: a plurality of repeatedly arranged pixel unit rows. Each pixel unit row includes at least one pixel unit group; each pixel unit group on each pixel unit row includes a first pixel and a second pixel which are adjacent to each other, and the first pixel and the second pixel respectively include three sub-pixels with different colors. In each pixel unit group, the three sub-pixels in the first pixel are arranged in the shape of a regular triangle, and the three sub-pixels in the second pixel are arranged in the shape of an inverted triangle. The shape of each sub-pixel is a polygon with more than four sides, such as pentagon, or a hexagon. Moreover, sub-pixels with the shapes are arranged staggeredly in dot form. Pixel arrangement plays an important role in the production of a metal mask. In the pixel arrangement mode provided by the embodiments of the present invention, compared with the conventional slot-shaped openings, the aperture ratio is greatly improved; and compared with diamond-shaped openings, RGB opening areas of the metal mask for vapor deposition provided by the embodiments of the present invention are relatively large, so that the manufacturing difficulty of the mask can be greatly reduced; the distance between openings is increased; the deformation of the mask in the stretching process can be effectively avoided; and the evaporation effect can be improved and the image resolution can be higher. That is to say, in the pixel arrangement structure provided by the embodiments of the present invention, as the luminous area of the pentagon or the hexagon is greater than that of the tetragonum, the luminous area is effectively increased and the non-luminous area is reduced. In addition, the opening areas of the metal mask for forming the pixel arrangement structure are also increased; the distance between the opening areas of the metal mask may also be increased; the strength of the metal mask is increased; the service life of the metal mask is prolonged; and the production cost is reduced. Moreover, the brightness and the service life of products can satisfy higher requirements; the yield of AMOLED products can be improved; the mass production of high-resolution AMOLED panels can be achieved; and the problem of image crosstalk can be avoided, so that the display image resolution can be high.

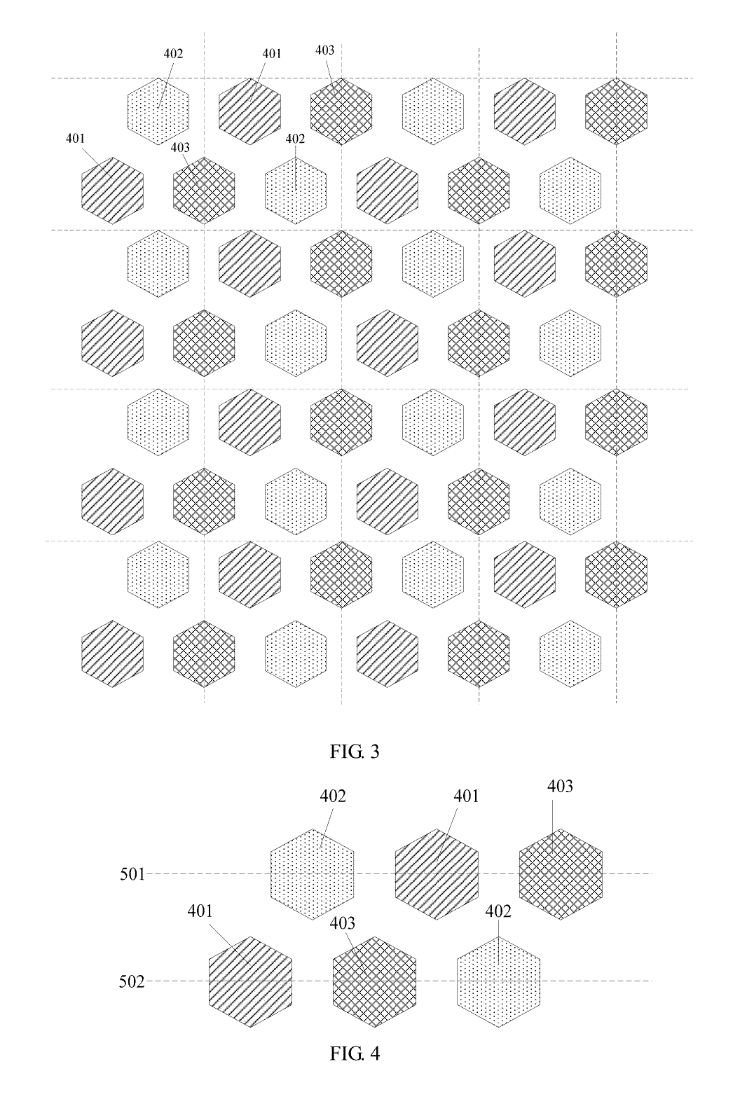

As illustrated in FIG. 3, for instance, opposite sides of any two adjacent sub-pixels are parallel to each other.

For instance, the area of each sub-pixel is equal to each other.

That is, in the embodiments of the present invention, adjacent sides of any two adjacent sub-pixels are parallel to each other and have equal length.

For instance, the distance between center points of any two adjacent sub-pixels with different colors is equal to each other.

For instance, each sub-pixel unit group respectively includes an R sub-pixel 401, a G sub-pixel 402 and a B sub-pixel 403.

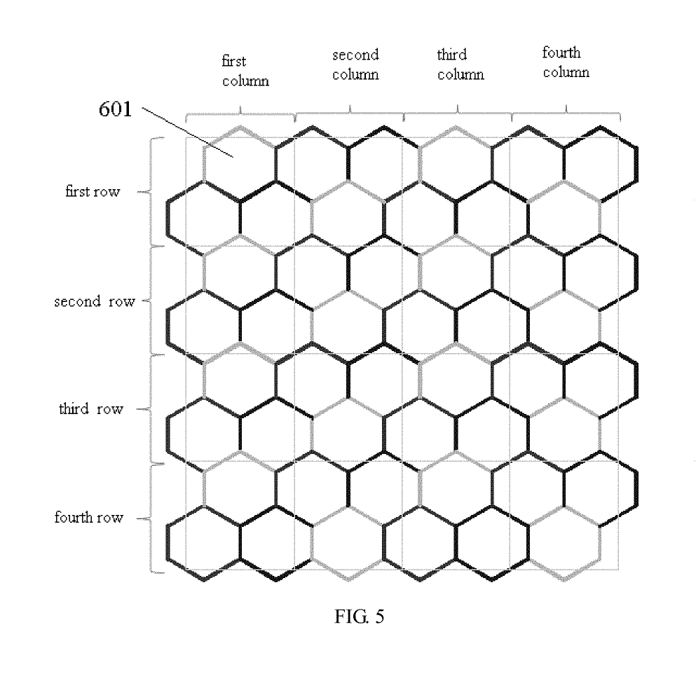

As illustrated in FIG. 4, in each pixel unit group, a center point of the G sub-pixel 402 in the first pixel and center points of the R sub-pixel 401 and the B sub-pixel 403 in the second pixel are sequentially arranged on a first straight line 501; center points of the R sub-pixel 401 and the B sub-pixel 403 in the first pixel, and a center point of the G sub-pixel 402 in the second pixel are sequentially arranged on a second straight line 502; the first straight line 501 and the second straight line 502 are parallel to each other, and the two straight lines extend along the row provided with the pixel unit group. The first straight line 501 is disposed over the second straight line 502.

For instance, as illustrated in FIG. 1 or 3, in the column direction, a pixel arranged in an odd column is the first pixel, and a pixel arranged in an even column is the second pixel; or a pixel arranged in the odd column is the second pixel, and a pixel arranged in the even column is the first pixel. It is noted that there is no clear border between adjacent columns.

An embodiment of the present invention provides an OLED device, which includes a base substrate and the pixel arrangement structure provided by an embodiment of the present invention disposed on the base substrate.

An embodiment of the present invention provides a display device, which includes the OLED device provided by an embodiment of the present invention.

Corresponding to the pixel arrangement structure as shown in FIG. 1, as illustrated in FIG. 5, an embodiment of the present invention provides a mask for forming the pixel arrangement structure provided by an embodiment of the present invention, which includes: a substrate, and opening areas 601 being disposed on the substrate and corresponding with the sub-pixels in the pixel arrangement structure one to one, respectively. The shape of an FMM opening corresponding to each sub-pixel is also a hexagon. Two adjacent sides of any two adjacent FMM openings are parallel to each other and have equal length. The opening areas of the FMM corresponding to different sub-pixels in each row are arranged in a stagger manner so that the opening areas of the FMM corresponding to the sub-pixels are also arranged in a shape like a honeycomb.

The mask provided by embodiments of the present invention may be a metal mask. The shape, the size and the position of the opening areas disposed on the metal mask depend on the pixel arrangement structure provided by the embodiments of the present invention. The opening areas of the mask are in one-to-one correspondence with the sub-pixels in the pixel arrangement structure.

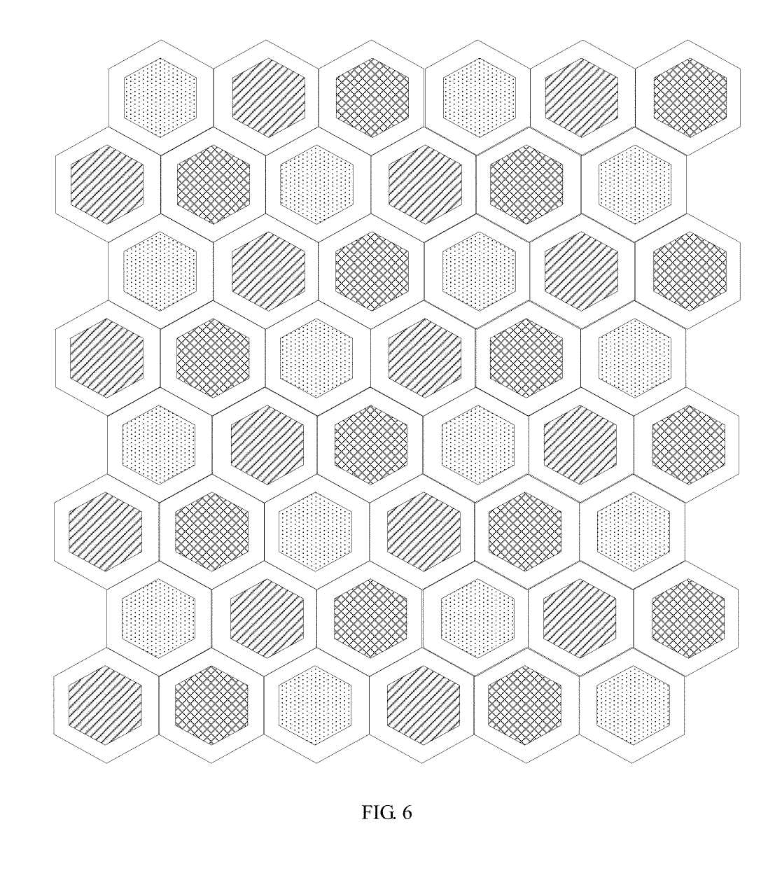

FIG. 6 illustrates the corresponding relationship between the pixel arrangement structure provided by an embodiment of the present invention and the opening areas of the mask. A luminous area of each sub-pixel corresponds to an opening area. The mask effectively increases the luminous area and reduces the non-luminous area. In addition, the opening areas of the metal mask for forming the pixel arrangement structure are also increased; the distance between the opening areas of the metal mask may also be increased; the strength of the metal mask is increased; the service life of the metal mask is prolonged; and the production cost is reduced. Moreover, as it adopts a non-pentile arrangement, the problem of image crosstalk can be avoided, and the display image resolution can be high.

Embodiments of the present invention provide a novel honeycomb real RGB pixel arrangement structure, which can help manufacturing of a high fine metal mask (FMM), and a pattern for forming the FMM. In the pixel arrangement structure, six sub-pixels are combined to form two pixels and form a repeating unit, and the 2 pixels are arranged in the same row of a thin-film transistor (TFT) substrate. Each pixel includes sub-pixels of three colors, namely R, G, B, and the shape of each of the three sub-pixels is a hexagon. Adjacent sides of any two adjacent sub-pixels are parallel to each other and have equal length. In three different sub-pixels in each row, any two adjacent sub-pixels are arranged staggeredly, i.e., they are not disposed on the same straight line, and connecting lines of center points of the sub-pixels are combined to form equilateral triangles, so that the FMM corresponding to the sub-pixels presents a shape like a honeycomb.

Correspondingly, the metal mask is made into a slot shape. The arrangement mode avoids the problem of color blending caused by strip openings of the metal mask. Under the condition of predetermined PDL Gap value, as the luminous area of the hexagon is greater than that of the tetragonum, the luminous area is effectively increased and the non-luminous area is reduced. In addition, the opening areas of the metal mask for forming the pixel arrangement structure is also increased; the distance between the opening areas of the metal mask may be also increased; the strength of the metal mask is increased; the service life of the metal mask is prolonged; and the production cost is reduced. Meanwhile, not only high resolution can be achieved but also Real RGB can be achieved. Finally, the display image resolution of screens is high. As it is not a pentile arrangement and Real RGB is provided, problems of image crosstalk, worse jaggies of oblique lines and the like can be solved.

The design principle of the opening areas of the FMM corresponding to the RGB sub-pixels is that edges of FMM openings corresponding to the three sub-pixels are close to each other and the area is fully utilized. In the arrangement mode of the pixel arrangement structure provided by embodiments of the present invention, under the condition of equal PDL Gap, the opening areas of the FMM occupy the entire area of sub-pixel areas, meanwhile, the area of the opening areas of the FMM is also equal to each other (it may be not exactly the same, which it not limited in the embodiments of the present invention). However, as a luminous area of a sub-pixel in each opening area of a hexagonal FMM is greater than that of a sub-pixel in an opening area of a tetragonum FMM, the aperture ratio of the sub-pixel corresponding to the opening area of the hexagonal FMM is significantly increased, so that the service life of RGB LEDs can be significantly increased, which is very useful for the AMOLED products.

As described, in order to solve the problems of the restriction of the production of the metal mask by pixel arrangement and color blending of screens, improve the aperture ratio, and prolong the service life of the AMOLED device, embodiments of the present invention provides a real RGB pixel arrangement structure which is helpful to the production of a metal mask for vapor deposition. The pixel arrangement structure is formed by the repeated arrangement of a basic unit which is 2 pixels formed by 6 sub-pixels. The shape of the luminous area of each sub-pixel is a hexagon. Two adjacent sides of luminous areas in any two adjacent sub-pixels are parallel to each other and have equal length. In three sub-pixels with different colors in each row, luminous areas of any two adjacent sub-pixels are arranged in a stagger manner, so that FMM openings corresponding to the luminous areas of the sub-pixels are arranged in a shape like a honeycomb.

The foregoing is only the exemplary embodiments of the present invention and not intended to limit the scope of the present invention. The scope of the present invention is defined by the appended claims.

The application claims the benefits and priority of the Chinese patent application No. 201510254661.1 filed on May 18, 2015, which is incorporated herein by reference in its entirety.

1. A pixel arrangement structure, comprising a plurality of pixels, each pixel including three sub-pixels with different colors, wherein connecting lines of center points of the sub-pixels form equilateral triangles; and each sub-pixel has a shape of polygon with more than four sides.

2. The pixel arrangement structure according to claim 1, wherein the shape of each sub-pixel is a regular hexagon.

3. The pixel arrangement structure according to claim 2, further comprising a plurality of repeatedly arranged pixel unit rows; wherein each pixel unit row includes at least one pixel unit group; each pixel unit group on each pixel unit row is formed by two pixels; a center point of a sub-pixel of the first color in the first pixel and center points of a sub-pixel of the second color and a sub-pixel of the third color in the second pixel are provided on the same straight line; center points of a sub-pixel of the second color and a sub-pixel of the third color in the first pixel and a center point of a sub-pixel of the first color in the second pixel are provided on the same straight line; and adjacent sides of any two adjacent sub-pixels are parallel to each other and have equal length.

4. The pixel arrangement structure according to claim 3, wherein each pixel unit group on each pixel unit row includes two pixels which are respectively a first pixel and a second pixel; the first pixel and the second pixel are adjacent to each other; connecting lines of center points of three sub-pixels in the first pixel form a regular triangle; and connecting lines of center points of three sub-pixels in the second pixel form an inverted triangle.

5. The pixel arrangement structure according to claim 4, wherein each pixel respectively includes a red (R) sub-pixel, a green (G) sub-pixel and a blue (B) sub-pixel;
wherein, in each pixel unit group, a center point of a G sub-pixel in the first pixel and center points of an R sub-pixel and a B sub-pixel in the second pixel are sequentially arranged on a first straight line; center points of an R sub-pixel and a B sub-pixel in the first pixel and a center point of a G sub-pixel in the second pixel are sequentially arranged on a second straight line; the first straight line is parallel to the second straight line; and the two straight lines extends along the row provided with the pixel unit group.

6. The pixel arrangement structure according to claim 5, wherein, in a column direction, a pixel arranged in an odd column is the first pixel, and a pixel arranged in an even column is the second pixel; or a pixel arranged in the odd column is the second pixel, and a pixel arranged in the even column is the first pixel.

7. The pixel arrangement structure according to claim 6, wherein the sub-pixel of the first color in the first pixel is adjacent to the sub-pixel of the second color or the sub-pixel of the third color in the second pixel in two adjacent columns of pixels; the sub-pixel of the second color in the first pixel is adjacent to the sub-pixel of the first color in the second pixel in the two adjacent columns of pixels; and the sub-pixel of the third color in the first pixel is adjacent to the sub-pixel of the first color in the second pixel in the two adjacent columns of pixels.

8. The pixel arrangement structure according to claim 1, wherein opposite sides of any two adjacent sub-pixels are parallel to each other.

9. The pixel arrangement structure according to claim 1, wherein the side length of each sub-pixel is equal.

10. The pixel arrangement structure according to claim 1, wherein distance between center points of any two adjacent sub-pixels with different colors is equal to each other.

11. An organic light-emitting diode (OLED) device, comprising a base substrate and the pixel arrangement structure according to claim 1 provided on the base substrate.

12. A display device, comprising the OLED device according to claim 11.

13. A mask for forming the pixel arrangement structure according to claim 1, comprising: a substrate, and opening areas provided on the substrate and corresponding with the sub-pixels in the pixel arrangement structure one to one, respectively.

14. The pixel arrangement structure according to claim 2, wherein the side length of each sub-pixel is equal.

15. The pixel arrangement structure according to claim 3, wherein the side length of each sub-pixel is equal.

16. The pixel arrangement structure according to claim 2, wherein distance between center points of any two adjacent sub-pixels with different colors is equal to each other.

17. The pixel arrangement structure according to claim 3, wherein distance between center points of any two adjacent sub-pixels with different colors is equal to each other.
